(19) United States
(12) Patent Application Publication
(10) Pub. No.: US 2026/0182333 A1
(43) Pub. Date: Jun. 25, 2026

(54) APPARATUS INCLUDING TSV AND MULTIPLE INSULATING MATERIALS

(71) Applicant: MICRON TECHNOLOGY, INC., BOISE, ID (US)

(72) Inventor: Tomohiko Kudo, Higashi Hiroshima-shi (JP)

(73) Assignee: MICRON TECHNOLOGY, INC., Boise, ID (US)

(21) Appl. No.: 19/422,643

(22) Filed: Dec. 17, 2025

Related U.S. Application Data
(60) Provisional application No. 63/736,543, filed on Dec. 19, 2024.

(51) Int. Cl. H10W 20/20; H10W 20/47; H10W 20/48; H10W 90/20

(52) U.S. Cl. CPC H10W 20/2134; H10W 20/47; H10W 90/297; H10W 20/48

(57) ABSTRACT

Some embodiments of the disclosure provide an apparatus comprising a plurality of wirings in a metal layer, a through-silicon via (TSV) coupled to at least one first wiring of the plurality of wirings, and an insulating layer under the metal layer. The insulating layer includes a first portion in a first region where the TSV is provided and configured to cover at least top part of the TSV. The insulating layer includes a second portion in a second region where the TSV is not provided. The second insulating portion includes a second insulating material (e.g., SiO or SiOC) different from a first insulating material (e.g., SiCN) of the first insulating portion. One or more second wirings of the plurality of wirings may be located in the second region for supplying a higher voltage than other wirings of the plurality of wirings in the metal layer.

### CROSS-REFERENCE TO RELATED APPLICATIONS

This application claims the filing benefit of U.S. Provisional Application No. 63/736,543, filed Dec. 19, 2024. This application is incorporated by reference herein in its entirety and for all purposes.

### BACKGROUND

High data reliability, high speed of memory access, lower power consumption, and reduced chip size are features that are demanded from semiconductor memory devices. A three-dimensional (3D) memory device may be formed by stacking a plurality of memory dies (or memory chips) and interconnecting the stacked memory dies using a plurality of through-silicon vias (TSVs). Benefits of the 3D memory device include shorter interconnects which reduce signal delays and power consumption, a greater number of vertical vias between layers which allow wide bandwidth buses between functional blocks in different layers, and a considerably smaller footprint. Thus, the 3D memory device contributes to higher memory access speed, lower power consumption, and chip size reduction. Example 3D memory devices include a High Bandwidth Memory (HBM) DRAM and a Hybrid Memory Cube (HMC) DRAM.

### BRIEF DESCRIPTION OF THE DRAWINGS

FIGS. 1A and 1B depict at least part of an example apparatus in a vertical cross-sectional view and a horizontal cross-sectional view, respectively, according to some embodiments of the disclosure.

FIG. 1C is an example graph showing time dependent dielectric breakdown (TBBD).

FIGS. 2A and 2B depict at least part of an example apparatus in a vertical cross-sectional view and a horizontal cross-sectional view, respectively, according to some embodiments of the disclosure.

FIGS. 3A-3E depict example processes of manufacturing an example apparatus in a cross-sectional view according to some embodiments of the disclosure.

FIGS. 4A-4F depict example processes of manufacturing an example apparatus in a cross-sectional view according to some embodiments of the disclosure.

FIG. 5 depicts a schematic configuration of an example semiconductor system according to an embodiment of the disclosure.

FIG. 6 is a block diagram of an example semiconductor device according to some embodiments of the disclosure.

### DETAILED DESCRIPTION

Various example embodiments of the disclosure and combinations thereof will be described below in detail with reference to the accompanying drawings. The following detailed descriptions refer to the accompanying drawings that show, by way of illustration, specific aspects in which embodiments of the disclosure may be practiced. These embodiments are described in sufficient detail to enable those skilled in the art to practice the disclosure. Other embodiments may be utilized, and structure, logical and electrical changes may be made without departing from the scope of the disclosure. The various embodiments disclosed herein are not necessary mutually exclusive, as some disclosed embodiments can be combined with one or more other disclosed embodiments to form new embodiments.

In the descriptions, common or related elements and elements that are substantially the same are denoted with the same signs, and the descriptions thereof may be reduced or omitted. In the drawings, some of the same signs may be omitted for the same or substantially the same elements for ease of illustration. In the drawings, the dimensions and dimensional ratios of each unit do not necessarily match the actual dimensions and dimensional ratios in the embodiments.

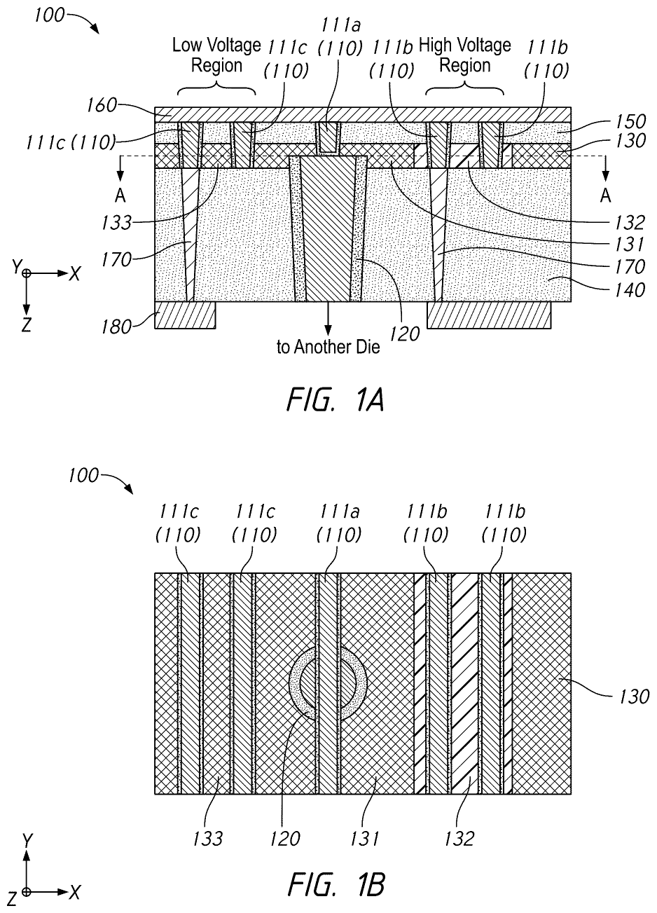

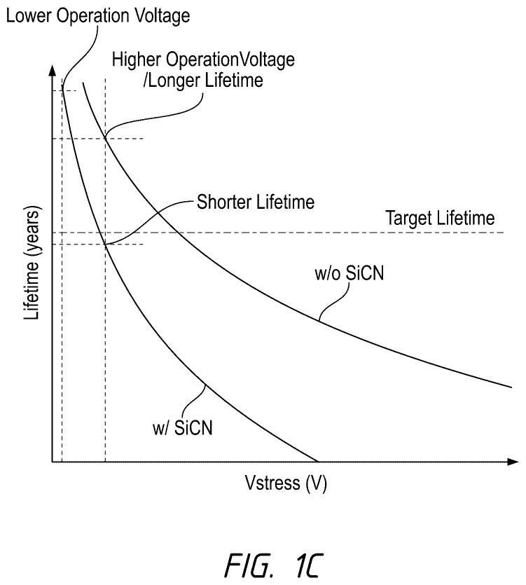

FIG. 1A depicts at least part of an example apparatus 100 in a vertical cross-sectional view according to some embodiments of the disclosure. FIG. 1B depicts at least part of the example apparatus 100 in a horizontal cross-sectional view at an A-A line in FIG. 1A according to some embodiments of the disclosure. The apparatus 100 may be a semiconductor device. The apparatus 100 may be a memory device, such as a dynamic random-access memory (DRAM). The apparatus 100 may be a logic device. The apparatus 100 according to the present embodiments includes a plurality of wirings 111 in a metal layer 110, a through-silicon-via (TSV) 120 coupled to at least one (herein referred to as a first wiring 111a) of the plurality of wirings 111, and an insulating layer 130 under the metal layer 110. The insulating layer 130 has a first portion 131 including a first insulating material and a second portion 132 including a second insulating material different from the first insulating material. The first portion 131 is provided in a region (herein may also be referred to as a first region) where the TSV 120 is provided and covers at least a top part of the TSV 120. The second portion 132 is provided in a region (herein may also be referred to as a second region) where the TSV 120 is not provided.

The plurality of wirings 111 in the metal layer 110 are arranged in parallel with each other in a first horizontal direction (for example, an x-axis direction in the drawing) and each extend in a second horizontal direction (for example, a y-axis direction in the drawing) orthogonal to the first horizontal direction. The plurality of wirings 111 may be metal wirings. The plurality of wirings 111 may be interconnects. The metal wiring layer 110 may be provided above another metal wiring layer 180 on a semiconductor substrate. The layer 180 may be a lower metal layer, and the layer 110 may be an upper metal layer. In some embodiments, the lower metal layer 180 and the upper metal layer 110 may be referred to as, for example, Mx and Mx+1 (where x=0, 1, 2, . . . ), respectively. In some embodiments, the metal layer 180 may be a local interconnect layer, which may also be referred to as Ly (where y=0, 1, 2, . . . ). In some embodiments, the lower metal layer or the local interconnect layer may be coupled to transistors in a semiconductor substrate. In some embodiments, the metal layer 110 may be provided above a semiconductor substrate where transistors are formed.

The TSV 120 is arranged extending in a vertical direction (for example, a z-axis direction in the drawing). In the extended A top part of the TSV 120 is coupled to the first wiring 111a of the plurality of wirings 111. In the depicted example, at least part of the TSV 120 extends through an insulating layer 140. The insulating layer 140 may include an insulating material, such as silicon dioxide (SiO₂). In some embodiments, a bottom part of the TSV 120 may be coupled to another wiring or conductive layer. In some embodiments, the TSV 120 may extend through semiconductor substrates of first and second dies stacked on one another and couple wirings or interconnects in the first die to wirings or interconnects in the second die under the first die. In the case of a memory device, such as a DRAM, the dies connected by one or more TSVs may include core memory dies and an interface die. In the depicted example, some of the plurality of wirings 111 other than the first wiring 111a may be coupled to corresponding wirings in a lower metal layer, a local interconnect layer, or the like, such as the metal layer 180, by corresponding vertical contacts 170 provided in the insulating layer 140 extending in the z-axis direction. The contacts 170 may include a conductive material, such as tungsten (W).

The insulating layer 130 is arranged on the insulating layer 140. The apparatus 100 may further include another insulating layer 150 including a low-k dielectric material, such as silicon oxycarbide (SiOC). The insulating layer 130 may be arranged between the insulating layer 140 and the insulating layer 150. The insulating layers 130 and 150 may be provided in the same layer level as the metal layer 110. The wirings 111 in the metal layer 110 each extend in the z-axis direction through the insulating layers 130 and 150. The apparatus 100 may include still another insulating layer 160 on the insulating layer 150. The insulating layer 160 may include an insulating material, such as silicon carbonitride (SiCN). The insulating layer 160 may be a barrier layer to prevent diffusion of a conductive material, such as copper (Cu), of the wirings 111. In some embodiments, there may be further provided vertical contacts, metal wiring layers, interconnects, or the like above the depicted configuration (for example, on the insulating layer 160) in a semiconductor device such as a semiconductor memory device and a semiconductor logic device.

The insulating layer 130 may be a barrier layer that prevents diffusion of a conductive material, such as copper (Cu), of the TSV 120. In some embodiments, the core conductive part of the TSV 120 may have at least on side surfaces thereof an insulating film or a dielectric film as a liner, including for example a nitride, an oxide, or a combination thereof. The insulating layer 130 may also be used for processes to form the TSV 120, such as chemical-mechanical polishing (CMP). The insulating layer 130 has a first portion 131 that is provided in the first region where the TSV 120 is provided and covers at least an exposed top part of the TSV 120 to block the TSV conductive material from entering other layers around the TSV 120. The first portion 131 may include a first insulating material capable of preventing the diffusion of the TSV conductive material. In some embodiments, the first insulating material may include silicon carbonitride (SiCN). The first insulating material may include at least one of SiCN, AlON, or AlOCN.

In the present embodiments, the insulating layer 130 also has a second portion 132 in the second region where the TSV 120 is not provided. The second portion 132 may include a second insulating material different from the first insulating material. In some embodiments, the second insulating material may include for example an oxide. In some embodiments, the second insulating material may include silicon oxide (SiO). In some embodiments, the second insulating material may include a low-k dielectric material, such as silicon oxycarbide (SiOC). In some embodiments, the second region where the second portion 132 is provided has one or more second wirings 111b of the plurality of wirings 111 located.

In the present embodiments, the insulating layer 130 may also have a third portion 133 including a third insulating material, provided in a region (herein may also be referred to as a third region) where one or more third wirings 111c of the plurality of wirings 111 are located. In some embodiments, the one or more second wirings 111b in the second region (or the second insulating portion 132) may be for supplying a higher voltage than the one or more second wirings 111c in the third region (or the third insulating portion 133). In the case of a memory device, such as a DRAM, the second wirings 111b may include, for example, wirings to supply voltage to word lines coupled to memory cells, sub-word line drivers, or the like, and the third wirings 111c may include, for example, wirings to supply voltage to transistors of various circuits, such as sense amplifiers and peripheral circuits. As one example, the voltage supplied by the second wirings 111b may be 3V or about 3V, and the voltage supplied by the third wirings 111c may be 1V or about 1V. In the case of a logic device, as one example, the second wirings 111b may supply voltage of less than or equal to 1V or about 1V to, for example, a core, and the third wirings 111c may supply voltage of equal to or less than 3V or around 3V (such as 3.3V or 2.5V) to, for example, input/output terminals.

The apparatus 100 including the insulating layer 130 having at least two different insulating materials, that is the two insulating portions (e.g., 131 and 132) including the two different insulating materials, one being for example SiCN and another being for example an oxide such as SiO and SiOC, can effectively improve the time dependent dielectric breakdown (TDDB) characteristic of the metal layer 110/wirings 111b. In an apparatus including only a single insulating material, such as SiCN, in the insulating layer (e.g., 130), a leak current may flow in the SiCN insulating layer and/or at an interface between the SiCN insulating layer and the low-k insulating layer (e.g., 150), which may deteriorate TDDB. By providing the second insulating portion 132 including the insulating material (e.g., an oxide such as SiO and SiOC (low-k)) different from the SiCN insulating layer, the TDDB deterioration can be prevented or mitigated. The apparatus 100 can hence further the longevity of a semiconductor device, such as a memory device and a logic device. More specifically, for example, as shown in FIG. 1C, the TDDB between the two neighboring second wirings 111b in the second region where the second portion 132 of the second insulating material (e.g., SiO or SiOC) is provided may exhibit a longer lifetime (years; see the curve “w/o SiCN” in FIG. 1C) than the two neighboring third wirings 111c in the third region where the third portion 133 of the third insulating material (e.g., SiCN) is provided (see the curve “w/SiCN” in FIG. 1C). The third insulating material of the third portion 133 is the same as the first insulating material of the first portion 131. Thus, the second wirings 1l1b are more sustainable at least in terms of requiring a longer time to reach a breakdown point than the third wirings 111c when the same voltage stress (Vstress) is applied to the second and third wirings 111b and 111c. In other words, if the same lifetime is to be expected, the second wirings 111b can withstand a greater Vstress over the years than the third wirings 111c. Furthermore, in the configuration according to the present embodiments, as illustrated in FIG. 1C, the use of the second portion 132 of the second insulating material in the higher voltage region (w/o SICN) can achieve a predetermined target lifetime. Still furthermore, the third portion 133 of the third insulting material can be used in the lower voltage region (w/SICN) to achieve the predetermined target lifetime.

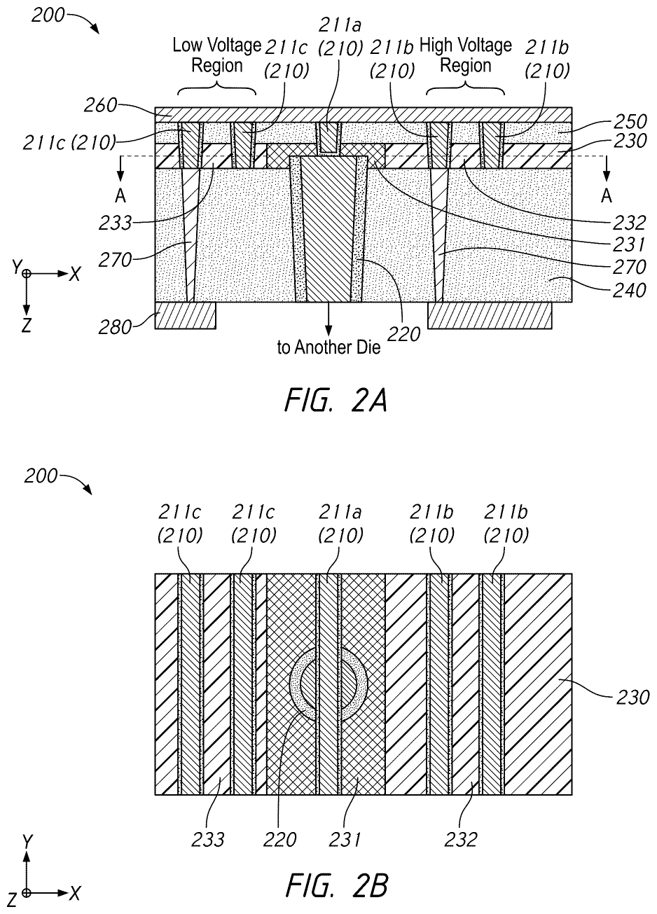

FIG. 2A depicts at least part of an example apparatus 200 in a vertical cross-sectional view according to some embodiments of the disclosure. FIG. 2B depicts at least part of the example apparatus 200 in a horizonal cross-sectional view at an A-A line in FIG. 2A according to some embodiments of the disclosure. The apparatus 200 corresponds to the apparatus 100 in FIGS. 1A and 1, except that the third portion 233 of the insulating layer 230 also includes the same insulating material as the second insulating material (e.g., SiO or SiOC) of the second portion 232. This can further improve the lifetime of the TDDB of the wirings 211 of the metal layer 210 located in both the second and third portions 233 of the insulating layer 230 in the regions where the TSV is not provided. In the depicted example, the portions including 232 and 233 except for the first portion 231 are formed with the second insulating material different from the first insulating material. Other than the above, components of the apparatus 200, such as metal layer 210 (including wirings 211a-c), TSV 220, insulating layer 230 (including portions 231-233), insulating layers 240, 250 and 260, contacts 270, and lower metal layer 280, are the same or substantially the same as the corresponding components 110-180 of the apparatus 100, respectively. The details thereof are thus omitted.

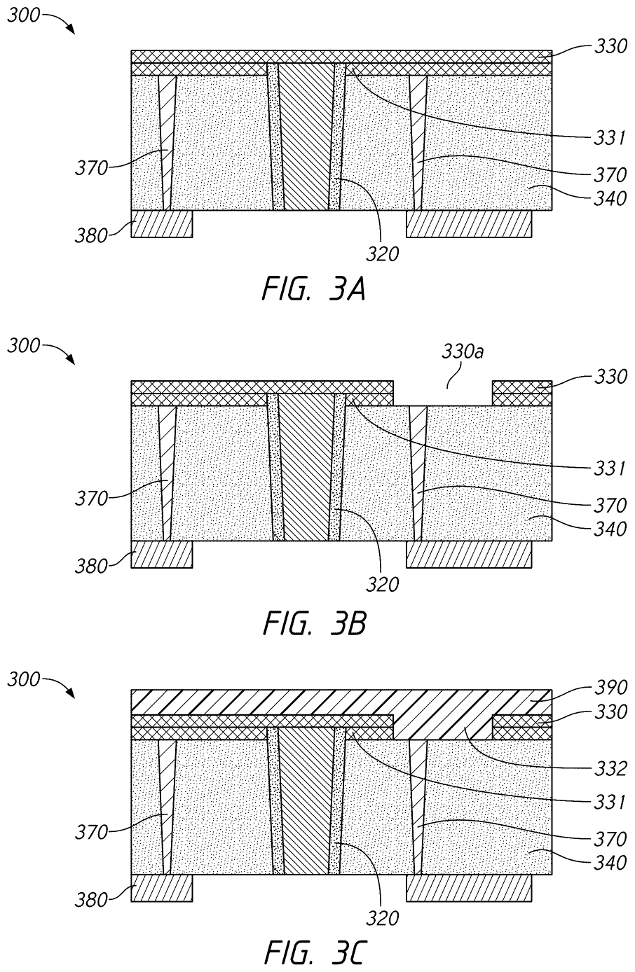

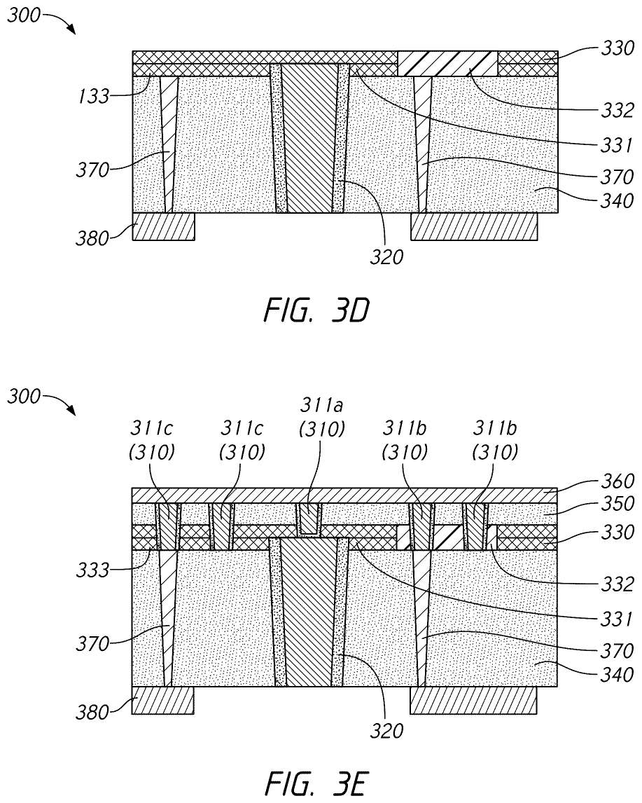

FIGS. 3A-3E depict example processes of manufacturing an example apparatus 300 in a cross-sectional view according to some embodiments of the disclosure. The apparatus 300 may correspond to the apparatus 100 in FIGS. 1A-1B. Sizes, positions, and the like of the components of the apparatus 300, however, may not be the same as those of the apparatus 100.

As shown in FIG. 3A, a TSV 320 and contacts 370 (e.g., 120 and 170 in FIG. 1A, respectively) are formed in an insulating layer 340 (e.g., 140 in FIG. 1A) by conventional methods, such as photolithography, dry etching, chemical vapor deposition, and chemical-mechanical polishing, as appropriate. Furthermore, an insulating layer 330 (e.g., 130 in FIG. 1A) is formed in the entire region surrounding the TSV 320. For example, the insulating layer 330 may be formed by two steps. First, a lower insulating film is provided for CMP of a top part of the TSV 320, and second, an upper insulating film is provided to cover the exposed top part of the TSV 320. In FIG. 3A, a horizontal line in the middle of the insulating layer 330 is illustrated to show the lower and upper insulating films. The insulating layer 330 may include an insulating material, such as SiCN. The lower and upper insulating films may include the same insulating material. The insulating layer 330 has a first portion 331 (e.g., 131 in FIG. 1A) in a region where the TSV 320 is provided.

As shown in FIG. 3B, a portion 330a of the insulating layer 330 in a region where the TSV 320 is not provided is removed by for example etch back. As shown in FIG. 3C, an insulating material 390, such as SiO, is then deposited on the insulating layer 330, covering a surface of the insulating layer 330 and filling the portion 330a. The filled portion 330a becomes a second portion 332 (e.g., 132 in FIG. 1A) including the second insulating material (e.g., SiO or SIOC) different from the first insulating material (e.g., SiCN) of the first portion 331.

Subsequently, as shown in FIG. 3D, the insulating material 390 is removed from the surface of the insulating layer 330 by for example CMP, and then, as shown in FIG. 3E, by using appropriate conventional methods, such as photolithography, dry etching, chemical vapor deposition, and chemical-mechanical polishing, an insulating layer 350 (e.g., 150 in FIG. 1A) is formed on the insulating layer 330, a metal layer 310 including wirings 311 (e.g., 110 and 111 in FIG. 1A) is formed penetrating through the insulating layers 330 and 350, and another insulating layer 360 (e.g., 160 in FIG. 1A) is formed on the insulating layer 330, covering top surfaces of the wirings 311. The wirings 311 include first wirings 311a (e.g., 111a in FIGS. 1A-1B) extending through the insulating layer 350 and the first portion 331 of the underlying insulating layer 330 in the region where the TSV 320 is provided and second wirings 311b (e.g., 111b in FIGS. 1A-1) extending through the insulating layer 350 and the second portion 332 of the insulating layer 330 in the region where the TSV 320 is not provided. The wirings 311 further include third wirings 311c (e.g., 111c in FIGS. 1A-1) extending through the insulating layer 350 and the third portion 333 of the insulating layer 330 in another region where the TSV 320 is not provided. The second wirings 311b may be for supplying a higher voltage than the third wirings 311c. Hence, the region where the second portion 332 of the insulating layer 330 (having the second insulating material, e.g., SiO or SiOC) and the second wirings 311b are located may be a high voltage region whereas the region where the third portion 333 of the insulating layer 330 (having the third insulating material, e.g., SiCN that is the same as the first insulating material of the first portion 331) and the third wirings 311c are located may be a low voltage region. By forming the apparatus 300 according to the present embodiments, it is possible to provide a semiconductor device, such as a memory device and a logic device, with a high voltage region having the improved TDDB characteristic. Such a high voltage region as well as a low voltage region can achieve a predetermined target lifetime (see the w/o SiCN curve and the w/SiCN curve in FIG. 1C).

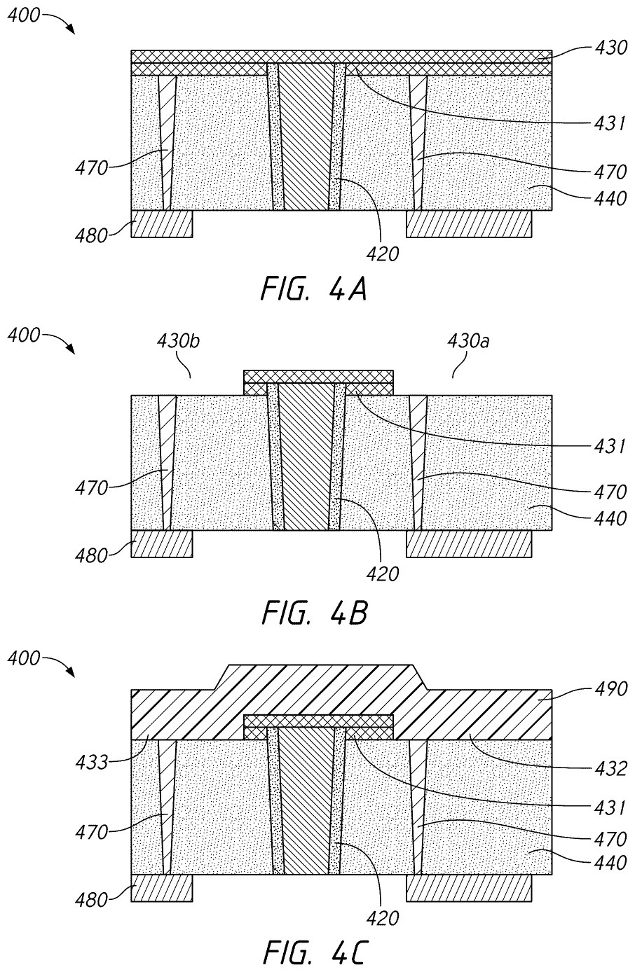

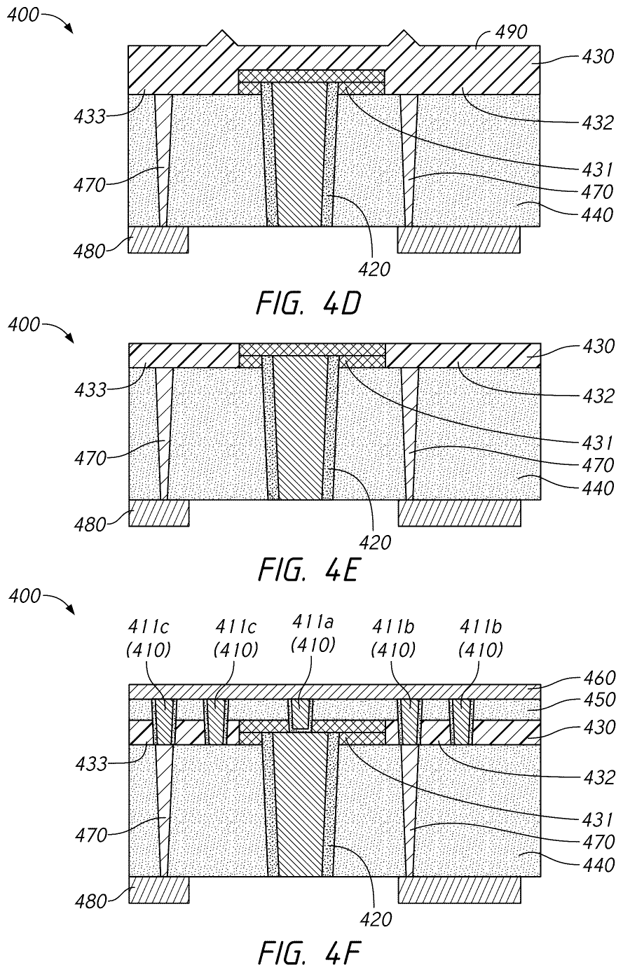

FIG. 4A-4F depict example processes of manufacturing an example apparatus 400 in a cross-sectional view according to some embodiments of the disclosure. The apparatus 400 may correspond to the apparatus 200 in FIGS. 2A-2B. Sizes, positions, and the like of the components of the apparatus 400, however, may not be the same as those of the apparatus 200.

In a similar manner to FIG. 3A, first, as shown in FIG. 4A, a TSV 420 and contacts 470 (e.g., 220 and 270 in FIG. 2A, respectively) are formed in an insulating layer 440 (e.g., 240 in FIG. 2A) by conventional methods, such as photolithography, dry etching, chemical vapor deposition, and chemical-mechanical polishing. Furthermore, an insulating layer 430 (e.g., 230 in FIG. 2A) is formed in the entire region including the TSV 420. The insulating layer 430 may include an insulating material, such as SiCN. The insulating layer 430 has a first portion 431 (e.g., 231 in FIG. 2A) where the TSV 420 is provided.

Next, as shown in FIG. 4B, portions 430a and 430b of the insulating layer 430 in regions where the TSV 320 is not provided are removed by for example etch back. As shown in FIG. 4C, an insulating material 490, such as SiO and SiOC, is then deposited on the removed portions 430a and 430b and the remaining portion of the insulating layer 430. The portions 430a and 430b filled with the insulating material 490 become a second portion 432 (e.g., 232 in FIG. 2A) and a third portion 433 (e.g., 233 in FIG. 2A), respectively. The second and third portions 432 and 433 include the insulating material 490 (e.g., SiO or SiOC) as the second and third insulating materials thereof, different from the first insulating material (e.g., SiCN) of the first portion 431. As shown in FIG. 4D, the insulating material 490 is removed by for example etch back,

Subsequently, as shown in FIG. 4D, the insulating material 490 is partially removed by for example etch back, and as shown in FIG. 4E, the insulating material 490 is fully removed from the surface of the insulating layer 430 by for example CMP. Then, as shown in FIG. 4F, in a similar manner to FIG. 3E, an insulating layer 450 (e.g., 250 in FIG. 2A), a metal layer 410 including wirings 411 (e.g., 210 and 211 in FIG. 2A), and another insulating layer 460 (e.g., 260 in FIG. 2A) are formed on the insulating layer 430 by appropriate conventional methods. The wirings 411 include first wirings 411a (e.g., 211a in FIGS. 2A-2B) extending through the insulating layer 450 and the first portion 431 of the underlying insulating layer 430 in a region where the TSV 420 is provided and second wirings 411b (e.g., 211b in FIGS. 2A-2B) extending through the insulating layer 450 and the second portion 432 of the insulating layer 430 in a region where the TSV 420 is not provided. The wirings 411 further include third wirings 411c (e.g., 211c in FIGS. 2A-2B) extending through the insulating layer 450 and the third portion 433 of the insulating layer 430 in another region where the TSV 420 is not provided. Similarly to the apparatus 300, in the apparatus 400, the second wirings 411b may be for supplying a higher voltage than the third wirings 411c. Since the insulating layer 430 includes the first portion 431 of the first insulating material (e.g., SiCN) and the second and third portions 432 and 433 of the same second and third insulating materials (e.g., SiO or SiOC) but different from the first insulating material, a semiconductor device with both a high voltage region and a low voltage region having improved TDDB characteristics can be achieved.

In FIGS. 1A-4F, the TSVs 120-420 are depicted adjacently to the contacts 170-470. According to some embodiments of the disclosure, for example, in the case of a memory device, such as a DRAM, the contacts 170-470 as well as the corresponding wirings 111 may be provided in a memory array region where memory cells and various circuits, such as sense amplifiers and sub-word line drivers, are arranged on each die, whereas the TSVs 120-420 may be provided in a designated TSV region in each of dies stacked on one another to couple the stacked dies, such as core dies and an interface die.

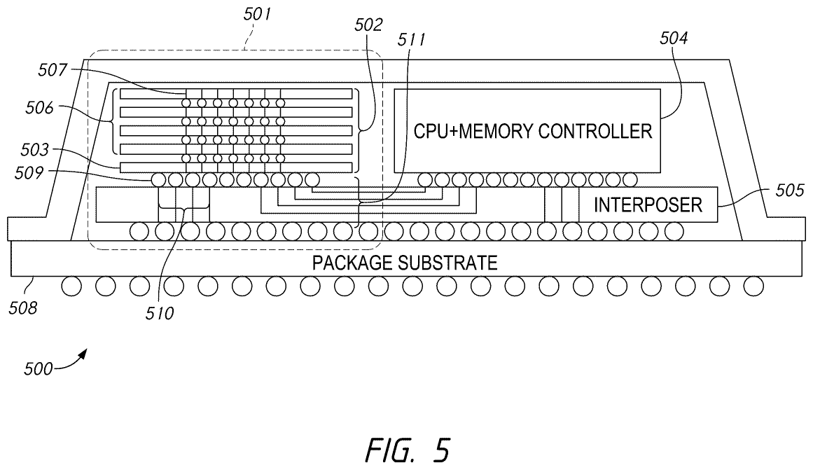

FIG. 5 depicts a schematic configuration of an example semiconductor system 500 according to some embodiments of the disclosure. The semiconductor system 500 may include an apparatus, which may be for example the apparatuses 100-400. The semiconductor system 500 includes a semiconductor memory device 501 in some embodiments of the disclosure. The semiconductor system 500 may also include a central processing unit (CPU) and memory controller 504, which may be a controller chip, on an interposer 505 on a package substrate 508. The interposer 505 may include one or more power lines 510 which may supply power supply voltage from the package substrate 508. The interposer 505 may include a plurality of channels 511 that may interconnect the CPU and memory controller 504 and the semiconductor memory device 501. The semiconductor memory device 501 may be a dynamic random access memory (DRAM). The memory controller 504 may provide a clock signal, a command signal, and may further transmit and receive data signals. The plurality of channels 511 may transmit the data signals between the memory controller and the memory device 501. The semiconductor memory device 501 may include a plurality of dies (or chips) 502 including at least one interface (IF) die (or chip) 503 and a plurality of memory core dies (or chips) 506 stacked with each other. A number of the memory core dies 506 may not be limited to four as in the illustrated example, and may be more or fewer as appropriate. Each of the memory core dies 506 may include a plurality of memory cells and circuitries accessing the memory cells. For example, the memory cells may be DRAM memory cells. The memory cells may be arranged in array. The semiconductor memory device 501 may include conductive vias 507 (such as the TSVs 120-420 in some embodiments of the disclosure) which couple the IF die 503 and the memory core dies 506 by penetrating the IF die 503 and the memory core dies 506. The IF die 503 may be coupled to the interposer 505 via interconnects 509. For example, the interconnects 509 may be microbumps having bump pitches of less than about or less than one hundred micrometers and exposed on an outside of the IF die 503. A portion of each of the interconnects 509 may be coupled to the one or more power lines 510. Another portion of each of the interconnects 509 may be coupled to one or more of the channels 511.

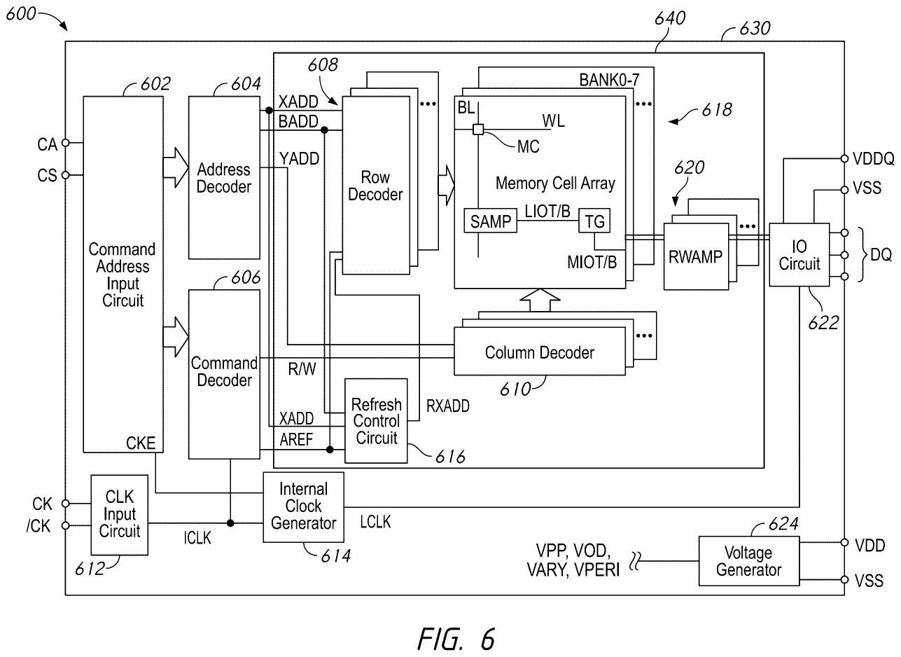

FIG. 6 is a block diagram of an example semiconductor device 600 according to some embodiments of the disclosure. The semiconductor device 600 may be a semiconductor memory device, such as a dynamic random-access memory (DRAM) device. The DRAM device may include an interface die and a plurality of core dies which are stacked on the interface die. In the example diagram of FIG. 6, certain components are shown located on an interface (IF) die 630, while other components are shown as part of each of core dies 640. For the sake of clarity, only a single core die 640 and its components are shown; however, there may be multiple core dies (e.g., 2, 4, 6, 8, 16, or more) each with similar components to each other. The example semiconductor device 600 of FIG. 6 shows a particular arrangement of components between the IF die 630 and the core die 640; however, other arrangements may be used in other embodiments. For example, a refresh control circuit 616 may be on the IF die 630 in some embodiments. For the sake of illustration, the core die 640 is drawn as a rectangular box which is smaller than the IF 630; however, the core die 640 and IF die 630 may have any size relationship to each other. For example, the core die 640 and IF die 630 may be approximately the same size. The IF die 630 may include or may be part of a logic die. In other embodiments, the bottom core die of the stacked core dies may take a role of an interface as a master chip, and the upper core dies may act as slave chips to receive control information from and transmit data to the bottom core die.

The semiconductor device 600 includes a memory array 618 on each of the core dies 640. The memory array 618 is shown as including a plurality of memory banks. In the embodiments of FIG. 6, the memory array 618 is shown as including eight memory banks BANK0-BANK7. More or fewer banks may be included in the memory array 618 of other embodiments. Each memory bank includes a plurality of word lines WL, a plurality of bit lines BL, and a plurality of memory cells MC arranged at intersections of the plurality of word lines WL and the plurality of bit line BL. Selection of the word line WL is performed by a row decoder 608 and selection of the bit lines BL is performed by a column decoder 610, each of which may also be located on each of the core dies 640. In the embodiments of FIG. 6, the row decoder 608 includes a respective row decoder for each memory bank and the column decoder 610 includes a respective column decoder for each memory bank. The bit lines BL are coupled to a respective sense amplifier (SAMP) of the memory array 618. Read data from the bit line BL is amplified by the sense amplifier SAMP, and transferred to read/write amplifiers (RWAMPs) 620 over complementary local data lines (LIOT/B), transfer gate (TG), and complementary main data lines (MIOT/B) which are coupled to RWAMP 620. Conversely, write data outputted from RWAMP 620 is transferred to the sense amplifier SAMP over the complementary main data lines MIOT/B, the transfer gate TG, and the complementary local data lines LIOT/B, and written in the memory cell MC coupled to the bit line BL.

The semiconductor device 600 may employ a plurality of external terminals located on the IF die 630 or the bottom core die. The external terminals may include command and address (CA) terminals coupled to a command and address bus to receive commands and addresses and a chip select (CS) signal, clock terminals to receive clocks CK and/CK, data terminals DQ to provide data, and power supply terminals to receive power supply potentials VDD, VSS, and VDDQ.

The clock terminals are supplied with external clocks CK and/CK that are provided to an input circuit 612. The external clocks CK and/CK may be complementary. The input circuit 612 generates an internal clock ICLK based on the CK and/CK clocks. The ICLK clock is provided to the command decoder 606 and to an internal clock generator 614. The internal clock generator 614 provides various internal clocks LCLK based on the ICLK clock. The LCLK clocks may be used for timing operation of various internal circuits. The internal clocks LCLK are provided to an input and output (IO) circuit 622 to time operation of circuits included in the IO circuit 622, for example, to data receivers to time the receipt of write data. In some embodiments, the internal clocks LCLK may include a read clock which is used to control the timing of read operations, and a write clock which is used to control the timing of write operations. In some embodiments, the internal clocks may be passed to the IO circuit 622. In some embodiments, the internal clocks may also be passed to internal components, such as RWAMP 620, of the core die 640.

The CA terminals may be supplied with memory addresses. The memory addresses supplied to the CA terminals are transferred, via a command/address input circuit 602, to an address decoder 604. The address decoder 604 receives the address and supplies a decoded row address XADD to the row decoder 608 and supplies a decoded column address YADD to the column decoder 610. The address decoder 604 may also supply a decoded bank address BADD, which may indicate the bank of the memory array 618 containing the decoded row address XADD and column address YADD. The CA terminals may be supplied with commands. Examples of commands include timing commands for controlling the timing of various operations, access commands for accessing the memory, such as read commands for performing read operations and write commands for performing write operations, as well as other commands and operations. The access commands may be associated with one or more row address XADD, column address YADD, and bank address BADD to indicate the memory cell(s) to be accessed.

The commands may be provided as internal command signals to the command decoder 606 via the command/address input circuit 602. The command decoder 606 includes circuits to decode the internal command signals to generate various internal signals and commands for performing operations. For example, the command decoder 606 may provide a row command signal to select a word line and a column command signal to select a bit line.

The semiconductor device 600 may receive an access command which is a read command. When a read command is received, and a bank address, a row address and a column address are timely supplied with an activate command and the read command, read data is read from memory cells in the memory array 618 corresponding to the row address and column address. The read command is received by the command decoder 606, which provides internal commands so that the read data from the memory cells in the memory array 618 is provided to RWAMP 620. The read data is output to outside the semiconductor device 600 from the data terminals DQ via the IO circuit 622.

The semiconductor device 600 may receive an access command which is a write command. When the write command is received, and a bank address, a row address and a column address are timely supplied with an activate command and the write command, write data is supplied through the DQ terminals to RWAMP 620. The write data supplied to the data terminals DQ is written to the memory cells in the memory array 618 corresponding to the row address and column address. The write command is received by the command decoder 606, which provides internal commands so that the write data is received by data receivers in the IO circuit 622. Write clocks may also be provided to the external clock terminals for timing the receipt of the write data by the data receivers of the IO circuit 622. The write data is supplied via the IO circuit 622 to RWAMP 620.

The semiconductor device 600 may also receive commands causing it to carry out one or more refresh operations as part of a self-refresh mode. In some embodiments, the self-refresh mode command may be externally issued to the semiconductor device 600. In some embodiments, the self-refresh mode command may be periodically generated by a component of the device. In some embodiments, when an external signal indicates a self-refresh entry command, the refresh signal AREF may also be activated.

The power supply terminals are supplied with power supply potentials VDD and VSS. The power supply potentials VDD and VSS are supplied to an internal voltage generator circuit 624. The internal voltage generator circuit 624 generates various internal potentials such as VPP, VOD, VARY, VPERI, and the like based on the power supply potentials VDD and VSS.

The power supply terminals are also supplied with power supply potential VDDQ. The power supply potential VDDQ is supplied to the IO circuit 622. The power supply potential VDDQ may be the same potentials as the power supply potential VDD in one instance. The power supply potential VDDQ may be different potentials from the power supply potential VDD in another instance. The power supply potential VDDQ are used for the IO circuit 622 so that power supply noise generated by the IO circuit 622 does not propagate to the other circuit blocks.

DRAM is merely one example, and the embodiments and the descriptions herein are not intended to be limited to DRAM. Memory devices other than DRAM, such as a static random-access memory (SRAM), a flash memory, an erasable programmable read-only memory (EPROM), a magnetoresistive random-access memory (MRAM), and a phase-change memory, can also be applied as the apparatuses of the present embodiments. Furthermore, devices other than memory, including logic ICs, such as a microprocessor and an application-specific integrated circuit (ASIC), are also applicable as the apparatuses according to the present embodiments.

Although various embodiments of the disclosure have been described in detail, it will be understood by those skilled in the art that embodiments of the disclosure may extend beyond the specifically described embodiments to other alternative embodiments and/or uses and modifications and equivalents thereof. In addition, other modifications which are within the scope of the disclosure will be readily apparent to those of skill in the art based on the described embodiments. It is also contemplated that various combination or sub-combination of the specific features and aspects of the embodiments may be made and still falling within the scope of the disclosure. It should be understood that various features and aspects of the embodiments can be combined with or substituted for one another in order to form varying mode of the embodiments. Thus, it is intended that the scope of the disclosure should not be limited by the particular embodiments described above.

What is claimed is:

1. An apparatus, comprising:
a plurality of wirings in a metal layer;
a through-silicon via (TSV) coupled to at least one first wiring of the plurality of wirings; and
an insulating layer under the metal layer comprising:
a first portion including a first insulating material, provided in a first region where the TSV is provided and configured to cover at least top part of the TSV; and
a second portion including a second insulating material different from the first insulating material, provided in a second region where the TSV is not provided.

2. The apparatus according to claim 1, wherein the insulating layer is a barrier layer to prevent diffusion of a conductive material of the TSV.

3. The apparatus according to claim 1, wherein the first insulating material of the first portion of the insulating layer comprises a material capable of preventing diffusion of a conductive material of the TSV.

4. The apparatus according to claim 1, wherein the first insulating material comprises silicon carbonitride (SiCN).

5. The apparatus according to claim 1, wherein the second insulating material of the second portion of the insulating layer comprises an oxide.

6. The apparatus according to claim 1, wherein
the second region is a region where one or more second wirings of the plurality of wirings are located,
the insulating layer further comprises a third portion including a third insulating material same as the first insulating material, provided in a third region where one or more third wirings of the plurality of wirings are located, and
the one or more second wirings in the second region are for supplying a higher voltage than the one or more third wirings in the third region.

7. The apparatus according to claim 1, wherein
the second region is a region where one or more second wirings of the plurality of wirings are located,
the insulating layer further comprises a third portion including a third insulating material same as the second insulating material, provided in a third region where one or more third wirings of the plurality of wirings are located, and
the one or more second wirings in the second region are for supplying a higher voltage than the one or more third wirings in the third region.

8. The apparatus according to claim 7, wherein the third insulating material comprises silicon oxide (SiO) or silicon oxycarbide (SiOC).

9. The apparatus according to claim 1, wherein the plurality of wirings in the metal layer are coupled to wirings in another metal layer.

10. The apparatus according to claim 1, wherein the TSV couples a first die to a second die under the first die.

11. The apparatus according to claim 1, wherein the apparatus includes a memory device or a logic device.

12. An apparatus, comprising:
a plurality of wirings in a metal layer;
a through-silicon via (TSV) coupled to at least one first wiring of the plurality of wirings; and
an insulating layer under the metal layer as a barrier layer for the TSV, the insulating layer comprising:
a first portion including a first insulating material, provided in a first region where the TSV is provided and configured to cover at least top part of the TSV;
a second portion including a second insulating material different from the first insulating material, provided in a second region where the TSV is not provided, the second region is a region where one or more second wirings of the plurality of wirings are located; and
a third portion including a third insulating material same as the first insulating material, provided in a third region where one or more third wirings of the plurality of wirings are located, wherein
the one or more second wirings in the second region are for supplying a higher voltage than the one or more third wirings in the third region.

13. The apparatus according to claim 12, wherein the first insulating material of the first portion of the insulating layer comprises a material capable of preventing diffusion of a conductive material of the TSV.

14. The apparatus according to claim 12, wherein the first insulating material comprises silicon carbonitride (SiCN).

15. The apparatus according to claim 12, wherein the second insulating material of the second portion of the insulating layer comprises silicon oxide (SiO) or silicon oxycarbide (SiOC).

16. The apparatus according to claim 12, wherein the plurality of wirings in the metal layer are coupled to wirings in another metal layer, and the TSV couples a first die to a second die under the first die.

17. An apparatus, comprising:
a plurality of wirings in a metal layer;
a through-silicon via (TSV) coupled to at least one first wiring of the plurality of wirings; and
an insulating layer under the metal layer as a barrier layer for the TSV, the insulating layer comprising:
a first portion including a first insulating material, provided in a first region where the TSV is provided and configured to cover at least top part of the TSV;
a second portion including a second insulating material different from the first insulating material, provided in a second region where the TSV is not provided, the second region is a region where one or more second wirings of the plurality of wirings are located; and
a third portion including a third insulating material same as the second insulating material, provided in a third region where one or more third wirings of the plurality of wirings are located, wherein
the one or more second wirings in the second region are for supplying a higher voltage than the one or more third wirings in the third region.

18. The apparatus according to claim 17, wherein the first insulating material of the first portion of the insulating layer comprises a material capable of preventing diffusion of a conductive material of the TSV.

19. The apparatus according to claim 17, wherein the first insulating material comprises silicon carbonitride (SiCN).

20. The apparatus according to claim 17, wherein the second insulating material of the second portion of the insulating layer comprises silicon oxide (SiO) or silicon oxycarbide (SiOC).
